(19) United States
(12) Patent Application Publication
(10) Pub. No.: US 2026/0086182 A1
(43) Pub. Date: Mar. 26, 2026

(54) METHOD FOR DETERMINING MECHANICAL TISSUE PARAMETERS AND ASSOCIATED METHODS AND DEVICES

(71) Applicants: INSTITUT NATIONAL DE LA SANTE ET DE LA RECHERCHE MEDICALE, Paris (FR); ASSISTANCE PUBLIQUE - HOPITAUX DE PARIS, Paris (FR); UNIVERSITE PARIS CITE, Paris (FR)

(72) Inventors: Philippe GARTEISER, Paris Cedex 18 (FR); Bernard VAN BEERS, Paris Cedex 18 (FR); Gwenaël PAGE, Paris Cedex 18 (FR)

(21) Appl. No.: 18/858,497

(22) PCT Filed: Apr. 19, 2023
(86) PCT No.: PCT/EP2023/060133

§ 371 Date: Oct. 21, 2024

(30) Foreign Application Priority Data
Apr. 20, 2022 (EP) 22305576.5

(51) Int. Cl. G01R 33/563; G01R 33/56

(52) U.S. Cl. CPC G01R 33/56358; G01R 33/5608

(57) ABSTRACT

The present invention concerns the assessment of mechanical tissue properties in vivo. For this, magnetic resonance elastography (MRE) is often used but suffers from a poor adaptability of the reconstruction process of the mechanical tissue properties based on the images taken by MRE. There is therefore a need for a method for determining mechanical parameters of a tissue of a subject, which is adapted to his/her specificities. The present invention provides with a novel reconstruction process fulfilling this need by a smart use of resampling. This improvement is also advantageous to diagnose chronic diseases or provide biomarkers/therapeutical targets relative to chronic diseases by using these better assessed mechanical tissue properties provided by the novel reconstruction process.

### TECHNICAL FIELD OF THE INVENTION

The present invention concerns a method for determining mechanical tissue parameters. The invention also relates to a method for diagnosing a chronic disease. The invention also concerns a method for identifying a therapeutic target for preventing and/or treating a chronic disease. The invention also relates to a method for identifying a biomarker, the biomarker being a diagnostic biomarker of a chronic disease, a susceptibility biomarker of a chronic disease, a prognostic biomarker of a chronic disease or a predictive biomarker in response to the treatment of a chronic disease. The invention also concerns a method for screening a compound useful as a medicine, the compound having an effect on a known therapeutical target, for preventing and/or treating a chronic disease. The invention also relates to the associated computer program products and a computer readable medium.

### BACKGROUND OF THE INVENTION

Magnetic resonance elastography (MRE) has long been recognized as an essential tool for assessing mechanical properties in vivo. MRE is a form of elastography that specifically leverages MRI to quantify and subsequently map the mechanical properties (elasticity or stiffness) of soft tissue. MRI designates magnetic resonance imaging and is a medical imaging technique used in radiology to form pictures of the anatomy and the physiological processes of the body. MRI scanners use strong magnetic fields, magnetic field gradients, and radio waves to generate images of the organs in the body. MRI belongs to the techniques linked to nuclear magnetic resonance.

MRE is dependent on the reconstruction process, in which the displacement wave fields acquired with an appropriately motion-encoded MRI sequence, are used to compute the local distribution of mechanical properties in the organ of interest.

Many different reconstruction processes have been proposed, such as methods based on local frequency estimates (LFE), algebraic inversion of the differential wave equation (AIDE), multifrequency dual viscoelastic reconstruction (MDEV and its wavenumber-based variant KMDEV), or iterative numerical methods.

In the process of direct MRE reconstruction, the shear modulus is retrieved from wave images, either by identifying local frequencies or through the computation of spatial derivatives. For both operations, the discrete nature of the data in the spatial domain has a strong influence on the results. Two regimes can be defined when considering the ratio between wavelength λ and spatial resolution α. When this spatial sampling ratio λ/α is elevated (many pixels per wavelength), the system becomes dominated by noise, as the variation in phase between adjacent pixels approaches signal variability. When the spatial sampling ratio is low on the contrary, the problem becomes undersampled as the Shannon-Nyquist limit is approached.

In the case of clinical MRE, the patients in any cohort present a range of different stiffness values (i.e. wavelengths), but by necessity all patients are sampled with a unique spatial resolution set during the prospective study design phase to ensure data consistency. Consequently, each individual patient is differently affected by discretization artifacts depending on its individual stiffness. This bias cannot easily be eliminated, since it would require to know a priori the stiffness value of each individual, which is by definition not known until the measurement is performed. Furthermore, even within a single individual, the spatial resolution cannot be generally optimal since the mechanical properties within the organ of interest may present spatial heterogeneities.

### SUMMARY OF THE INVENTION

There is a need for a method for determining mechanical parameters of a tissue of a subject, which is adapted to his/her specificities.

To this end, the specification describes a method for determining mechanical parameters of a tissue of a subject, the method being computer-implemented and comprising the following steps:
receiving at least one image of the tissue, each image being taken by a magnetic resonance elastography technique,
reconstructing stiffness maps with resampling of the shear wave displacement at several spatial resolutions,
estimating the shear wavelength at each pixel of each reconstructed stiffness map,
selecting for each pixel, the stiffness value of the reconstructed stiffness map fulfilling a selection criterion, the selection criterion being fulfilled when the ratio of the shear wavelength by the size of the pixel is comprised between 6 and 9, and
producing the final stiffness map by taking the selected stiffness value for each pixel.

According to further aspects of the method for determining mechanical parameters of a tissue, which are advantageous but not compulsory, the method for determining might incorporate one or several of the following features, taken in any technically admissible combination:
the selection criterion is fulfilled when the shear wavelength divided by the size of the pixel is the nearest from a value comprised between 6 and 8.
the value is comprised between 6.5 and 7.5.
during the reconstructing step, the number of spatial resolutions at which the shear wave displacement is resampled is superior to 3, preferably superior to 10.
each resampling of the shear wave displacement is performed with a multiplication factor, the multiplication factor being comprised between 0.5 and 1.5.
the reconstructing step comprises an unwrapping operation of the phase signal of each image.
the reconstructing step comprises a filtering operation with a Butterworth filter.
the reconstructing step comprises finding the stiffness value by inversion of the Helmholtz wave equation.

The specification also relates to a method for predicting that a subject is at risk of suffering from a chronic disease, the method for predicting at least comprising the step of:
carrying out the steps of a method for determining the mechanical parameters of the subject, to obtain determined parameters, the method for determining being as previously described, and
predicting that the subject is at risk of suffering from a chronic disease based on the determined parameters.

The specification further concerns a method for diagnosing a chronic disease, the method for diagnosing at least comprising the step of:
carrying out the steps of a method for determining mechanical parameters of the subject, to obtain determined parameters, the method for determining being as previously described, and
diagnosing a chronic disease based on the determined parameters.

The specification also relates to a method for identifying a therapeutic target for preventing and/or treating a chronic disease, the method comprising the steps of:
carrying out the steps of a method for determining mechanical parameters of a first subject, to obtain first determined parameters, the first subject being a subject suffering from the chronic disease, the method for determining being as previously described,
carrying out the steps of a method for determining mechanical parameters of a second subject, to obtain second determined parameters, the second subject being a subject not suffering from the chronic disease, method for determining being as previously described, and
selecting a therapeutic target based on the comparison of the first and second determined parameters.

The specification further concerns a method for identifying a biomarker, the biomarker being a diagnostic biomarker of a chronic disease, a susceptibility biomarker of a chronic disease, a prognostic biomarker of a chronic disease or a predictive biomarker in response to the treatment of a chronic disease, the method comprising the steps of:
carrying out the steps of a method for determining mechanical parameters of a first subject, to obtain first determined parameters, the first subject being a subject suffering from the chronic disease, the method for determining being as previously described,
carrying out the steps of a method for determining mechanical parameters of a second subject, to obtain second determined parameters, the second subject being a subject not suffering from the chronic disease, the method for determining being as previously described, and
selecting a biomarker based on the comparison of the first and second determined parameters.

The specification also relates to a method for screening a compound useful as a probiotic, a prebiotic or a medicine, the compound influencing a known therapeutic target, for preventing and/or treating a chronic disease, the method comprising the steps of:
carrying out the steps of a method for determining mechanical parameters of a first subject, to obtain first determined parameters, the first subject being a subject suffering from a chronic disease and having received the compound, the method for determining being as previously described,
carrying out the steps of a method for determining mechanical parameters of a second subject, to obtain second determined parameters, the second subject being a subject suffering from a chronic disease and not having received the compound, the method for determining being as previously described, and
selecting a compound based on the comparison of the first and second determined parameters.

The specification also relates to a computer program product comprising instructions which, when the program is executed by a computer, cause the computer to carry out the steps of a method as previously described.

The specification further concerns a computer-readable storage medium comprising instructions which, when executed by a computer, cause the computer to carry out the steps of a method as previously described.

### BRIEF DESCRIPTION OF THE DRAWINGS

The invention will be better understood based on the following description, which is given in correspondence with the enclosed figures and as an illustrative example, without restricting the object of the invention. In the enclosed figures:

FIG. 1 shows schematically a system and a computer program product which interaction enables to carry out a method for determining mechanical parameters of a tissue,

FIG. 2 illustrates different maps obtained at different stages of the method for determining mechanical parameters, and

FIGS. 3 to 7 are relative to experiments carried out by the Applicant.

### DETAILED DESCRIPTION OF THE PREFERRED EMBODIMENTS

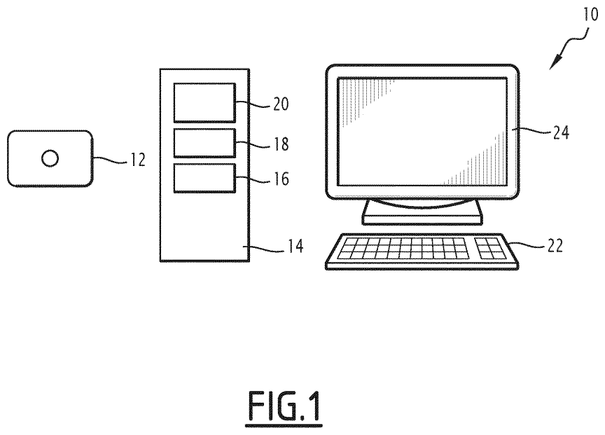

A system 10 and a computer program product 12 are represented in FIG. 1. The interaction between the computer program product 12 and the system 10 enables to carry out a method for determining mechanical parameters of a tissue, namely mechanical tissue parameters. The method for determining is thus a computer-implemented method.

System 10 is a computer. In the present case, system 10 is a laptop.

More generally, system 10 is a computer or computing system, or similar electronic computing device adapted to manipulate and/or transform data represented as electronic quantities within the computing system's registers and/or memories into other data similarly represented as physical quantities within the computing system's memories, registers or other such information storage, transmission or display devices.

System 10 comprises a processor 14, a keyboard 22 and a display unit 24.

The processor 14 comprises a data-processing unit 16, memories 18 and a reader 20. The reader 20 is adapted to read a computer readable medium.

The computer program product 12 comprises a computer readable medium.

The computer readable medium is a medium that can be read by the reader of the processor. The computer readable medium is a medium suitable for storing electronic instructions, and capable of being coupled to a computer system bus.

Such computer readable storage media are, for instance, disks, floppy disks, optical disks, CD-ROMs, magnetic-optical disks, read-only memories (ROMs), random access memories (RAMs), electrically programmable read-only memories (EPROMs), electrically erasable and programmable read only memories (EEPROMs), magnetic or optical cards, or any other type of medium for storing electronic instructions, and able to be coupled to a computer system bus.

A computer program is stored in the computer readable storage medium. The computer program comprises one or more stored sequences of program instructions.

The computer program is loadable into the data-processing unit and adapted to cause execution of the method for determining when the computer program is run by the data-processing unit.

Operation of the system 10 is now described by illustrating an example of carrying out the method for determining mechanical parameters of a tissue.

The method for determining comprises a step of receiving, a step of reconstructing, a step of estimating, a step of selecting and a step of producing.

During the step of receiving, the system 10 receives at least one image of the tissue.

For instance, the tissue is a tissue from the liver.

According to other examples, the tissue is a tissue from another organ, such as heart.

The tissue is a tissue from a subject, the subject being a mammal, notably a human.

The images are taken by a magnetic resonance elastography (MRE) technique. The technique involves a mechanical apparatus coupled to the patient near the organ of interest, which sends mechanical waves in synchrony with the MR imaging device. The resulting displacement waves propagate in the organ of interest, and an appropriate MR imaging sequence involving suitably timed motion-encoding gradients enables to encode the displacements as deviations in the phase images. Application of the motion encoding gradients along different physical axes enables to retrieve the different spatial directions of the displacement field. Application of the motion encoding gradients in increasing time offsets relative to the mechanical vibration enables to interrogate the time-dependence of the displacement field.

During the step of reconstructing, the system 10 reconstructs stiffness maps for several values of the shear wave displacement.

A stiffness map provides the stiffness values in an area.

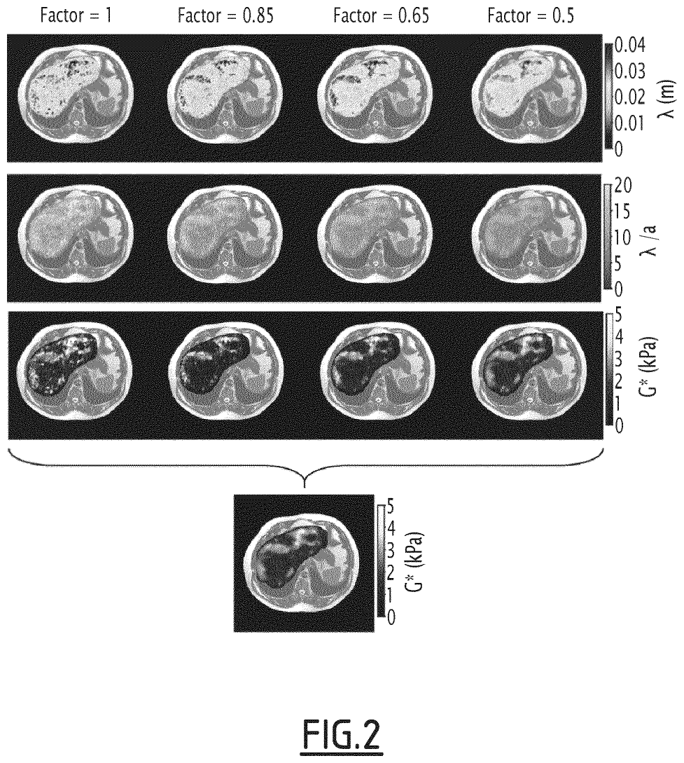

An example of stiffness map is given in FIG. 2 (last line).

Indeed, FIG. 2 illustrates different maps obtained at different stages of the method for determining mechanical parameters. More precisely, the liver maps illustrate MRE performed at 60 Hz where wavelength maps (top row), λ/a maps (middle row) and stiffness maps (bottom row) are reconstructed from resampled matrices of shear displacement. From these maps, a final stiffness map is obtained at the native spatial resolution of the dataset. Parametric maps are superimposed on a T2-weighted image.

Stiffness is the extent to which an object resists deformation in response to an applied force. By using only stiffness values, it is implicitly assumed that each tissue behaves as a solid.

During this step, for each value of the shear wave displacement, the system 10 performs a reconstruction operation.

Such reconstruction operation can be achieved by using the following formula:

$$G *= {ρω}^{2} \frac{\vert u \vert}{\vert {∇}^{2} u \vert}$$

wherein:
the magnitude of the complex quantity G* is the shear stiffness,
ρ is the density of the tissue, usually considered to be constant and equal to density of water (ρ=1000 kg·m⁻³)
ω is the frequency of the mechanical vibration used in the MRE technique, and
u is the shear displacement, defined as a time-resolved vector field in μm (micrometer).

More specifically, the system 10 carries out the reconstructing operation by implementing an algebraic inversion of the differential equation technique. Such technique is often named AIDE technique.

In the current example, the AIDE technique comprises an unwrapping operation, an extracting operation, a filtering operation and an inversion operation.

The unwrapping operation consists in unwrapping the MRI phase signal ¢ of each image, to obtain unwrapped images.

For instance, the unwrapping operation may be achieved based on weighted and unweighted least-square methods.

Both methods perform the unwrapping by minimizing the difference between the partial derivative of the observed phase and a trial partial derivative obtained by subtracting an integer multiple of 2π. Unwrapping is terminated when the multiples are found for each position in the image. The minimization method may be weighted to minimize the error propagation due to noise.

During the extraction operation, the system 10 extracts the complex-valued harmonic fields at the excitation frequency ω.

For this, the system 10 applies a Fourier transform operation on the unwrapped images.

This Fourier transform is applied over time (here four time steps).

Such operation enables to express the displacement fields in a compact form as an amplitude and a phase (complex-valued harmonic field) defined at each location in the image and for each encoded displacement direction.

During the filtering operation, the system 10 uses a spatiotemporal Butterworth filter.

Such filter is used to remove the long-wavelength compressional wave of the complex shear displacement u(r), where r denotes the spatial coordinate vector and u the value of the shear displacement.

Such filtering operation is performed in the bidimensional k-space to extract the complex shear displacement u(r) propagating in eight equally spread directions.

The filter is a bandpass filter which cut-in parameter ξᵢₙ and cut-off parameter ξ_{off} are respectively given by the following equations:

$${ξ}_{in} = \frac{ω}{R} \sqrt{\frac{ρ}{{μ}_{max}}} and {ξ}_{off} = \frac{ω}{R} \sqrt{\frac{ρ}{{μ}_{min}}}$$

wherein:
R the spatial resolution in pixels/m, and
μₘᵢₙ and μₘₐₓ are constant (which can, for instance, be set arbitrarily at 0.1 kPa and 20 kPa).

As an alternative to the filtering operation, removal operation can also be considered to remove the compressional waves. The removal operation is to apply the curl operator to the displacement field (∇·u). As the compression wave component is curl-free, application of the curl drops the compression components to zero while only keeping the shear wave components. During the inversion operation, G* was reconstructed by inversion of the Helmholtz wave equation. This implies that:

$$G *= {ρω}^{2} {\sum }_{n} \frac{\vert u ( n ) \vert}{\vert {∇}^{2} u ( n ) \vert}$$

Wherein n designates the direction of the filter, which, in this example, varies from 1 to 8 (since 8 directions are used during the filtering operation).

This reconstruction operation is carried out for several spatial resolutions of resampling of shear wave displacements.

The number of shear wave displacement spatial resolutions of resampling is the largest possible, notably superior to 4, preferably superior to 10.

Each spatial resampling of the acquired shear wave displacement is performed with a specific multiplication factor, and the multiplication factors are stored in an indexed table and accessed via their table index j.

This means that a resampling of the shear wave displacement uⱼ is a resampling of the acquired shear wave displacement which is performed with a resampling factor (RF) stored at index j of the indexed table of resampling factors.

In the current case, the reference field is the displacement field acquired at its native acquisition resolution, noted u_{ref}.

Mathematically, this can be written as:

$${u}_{j} = R ( {u}_{ref} , {RF}_{j} )$$

where R is the resampling operator, applying the resampling factor RFⱼ to the matrix u_{ref}.

Each resampling factor RFⱼ is comprised between 0.5 and 1.5.

As a specific example for 4 values, the resampling factors RFⱼ are respectively equal to 0.65, 0.8, 1 and 1.25.

The reconstruction operation for a spatial resolution of resampling of shear wave displacement uⱼ is then:

$${G}_{j}^{*} = {ρω}^{2} {\sum }_{n} \frac{\vert {u}_{j} ( n ) \vert}{\vert {∇}^{2} {u}_{j} ( n ) \vert}$$

Such operation can be seen as a resampling of the matrix of the unwrapped shear displacement by using a multiplication factor.

To resample matrices, a cubic interpolation kernel is used. For this operation, at each spatial position in the resampled displacement field, the value is obtained by fitting a third order, 2-dimensional polynomial to the vicinal datapoints in the displacement field matrix at its native acquisition resolution.

At the end of this step, in the current case, four stiffness maps are obtained for the values of rescaling, namely 1, 0.85, 0.65 and 0.5. These four stiffness maps are represented on the third line of FIG. 2.

During the estimating step, the system 20 estimates the shear wavelength λ at each pixel of each reconstructed stiffness map. In other words, a multiscale wavelength map is obtained by using the following formula:

$${λ}_{j} = \sqrt{\frac{{‖ G * ‖}_{j}}{ρ \cdot {ω}^{2}}}$$

where ∥X∥ designates the magnitude of the quantity X.

The result of such step for the four values of rescaling can be found on the first line of FIG. 2.

During the step of selecting, the system 10 selects for each pixel, the stiffness value of the reconstructed stiffness maps.

The system 10 selects the stiffness value, which fulfills a selecting criterion.

The selecting criterion is fulfilled, in this specific example, when the ratio s of the shear wavelength λ by the size a of the pixel is comprised between 6 and 9. This corresponds to the following equation:

$$6 \leq s = \frac{λ}{a} \leq 9$$

This corresponds to obtaining maps of λ/α. These maps are represented on the second line of FIG. 2.

In the present case, the value of 7 is chosen.

This means mathematically that the stiffness value G*(\vec{r}) is the value among the four for which the ratio λ/α is the closest to 7. In other words, the following equation is solved:

$$G * ( \vec{r} ) = \{ {G}_{j}^{*} ( r ) \vert {min}_{j} ( abs ( \frac{{λ}_{j} ( r )}{{a}_{j}} - 7 ) ) \}$$

More generally, a value comprised in an interval comprised between 6 and 9 (preferably 6 and 8, and more preferably 6.5 and 7.5) mentioned can be chosen instead of the value 7.

During the producing step, the system 10 produces the final stiffness map.

For this, the system 10 produces the final stiffness map by taking the selected stiffness value for each pixel.

The system 10 thus provides a set of stiffness values, which are the determined mechanical parameters for this example.

The complex components of the stiffness (shear storage modulus and shear loss modulus) and their derived metrics such as the phase angle can also be derived.

All these elements are mechanical tissue parameters.

To summarize, several stiffness maps and their relative wavelength maps are reconstructed at different spatial resolutions by resampling the shear displacement field. Then, a final stiffness map is provided at the native spatial resolution of the dataset by selecting at each position the value of the pixel coming from the map where the local value for the spatial sampling ratio λ/α is the closest to a value comprised between 6 and 9, and in the present example equal to 7.

This enables to enforce an optimal spatial sampling ratio condition at all positions in the regions of interest of any patient despite the spatial and inter-patient variations in mechanical wavelength. It differs from other multiscale methods based on filter banks because the proposed method is confined to a local operation in direct space, and because the scale sensitivity is introduced by retrospective resampling based on a sampling criterion rather than on a convolution operator.

The proposed method reduces the detrimental impact of the variability of discretization artifact that would otherwise be observed in a heterogeneous population of patients and in mechanically heterogeneous regions of interest.

This advantage is experimentally shown in the experimental section.

This section also shows that the method provides more accurateness and/or more robustness than prior state of the art techniques.

Such properties can advantageously be applied in other methods, the adaptation to these methods being immediate.

Notably, the method for post-processing may also be adapted for a method for diagnosing a chronic disease, a method for identifying a therapeutic target for preventing and/or treating a chronic disease, a method for identifying a biomarker, the biomarker being a diagnostic biomarker of a chronic disease, a susceptibility biomarker of a chronic disease, a prognostic biomarker of a chronic disease or a predictive biomarker in response to the treatment of a chronic disease and a method for screening a compound useful as a probiotic, a prebiotic or a medicine, the compound having an effect on a known therapeutic target, for preventing and/or treating a chronic disease.

Chronic diseases include cancer, type 2 diabetes, heart diseases, liver diseases such as fibrosis or non-alcoholic fatty liver diseases (NAFLD) and its most severe form, nonalcoholic steatohepatitis (NASH),

The embodiments and alternative embodiments considered here-above can be combined to generate further embodiments of the invention.

### Experimental Section

The validity of the proposed method, which is named MARS method hereinafter, is demonstrated in calibrated phantoms, in a repeatability study and in a cohort of patients with varying degrees of liver fibrosis. The performance of the method is compared to that of existing reconstruction methods on identical datasets to interrogate only the effects linked to the reconstruction rather than potential confounds arising from e.g. the quantity or nature of underlying data. In particular, homogeneous phantoms are used to assess whether each compared reconstruction has an effect on the average values that are retrieved in the absence of confounds from heterogeneities, physiologic motion and low SNR conditions. A repeatability study is carried out to compare the reconstructions on their ability to provide consistent results on the same patients. Finally, the reconstructions are compared in terms of their diagnostic merits in a cohort of patients with liver fibrosis levels typically encountered in nonalcoholic fatty liver disease.

The corresponding figures are the following:

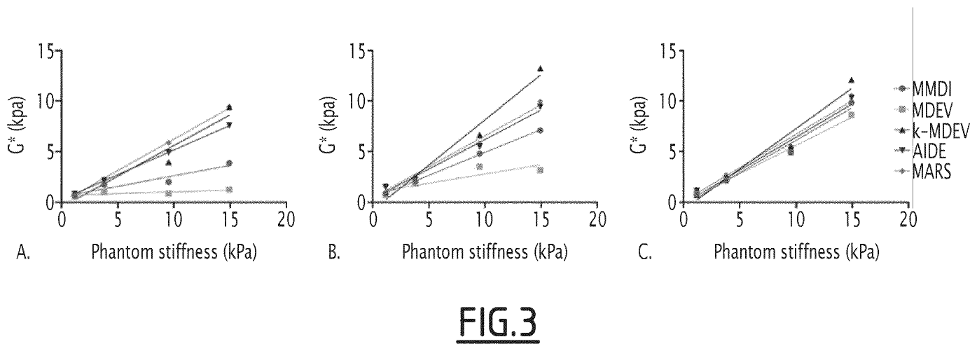

FIG. 3 provides graphs showing the linear regression between stiffness of the phantoms provided by the manufacturer and stiffness reconstructed with each method at (A.) 40 Hz, (B.) 60 Hz and (C.) 80 Hz. Slope, quality of fit (r²) and p values for each linear regression are indicated in the table 1. At 40 Hz, the MARS method shows a slope closest to 1 (slope=0.62, r²=0.99, p=0.0008), whereas at 60 Hz and 80 Hz k-MDEV method shows a slope closest to 1 (60 Hz: slope=0.90, r²=0.98, p=0.01; 80 Hz: slope=0.80, r²=0.96, p=0.021);

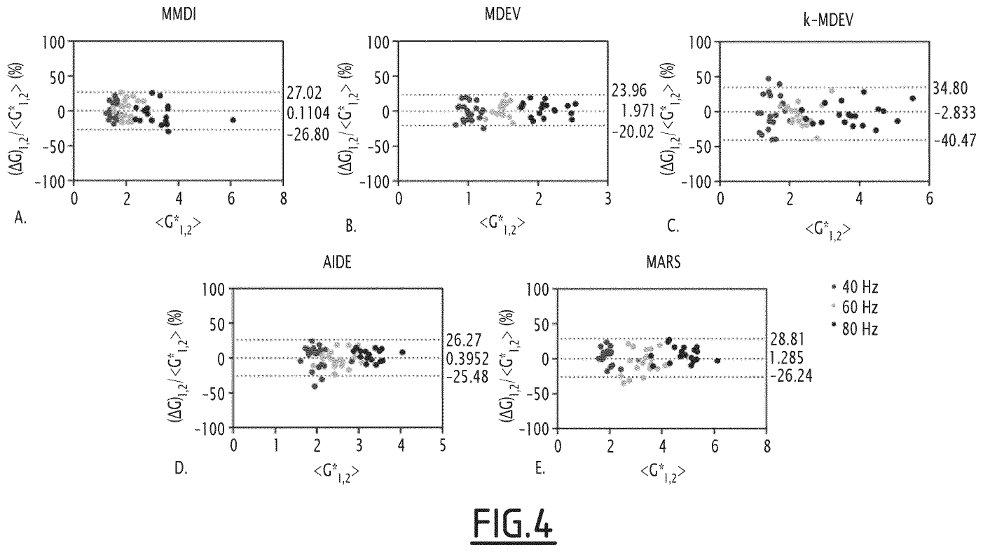

FIG. 4 illustrates graphs corresponding to Bland-Altman analysis of the measurement repeatability (A.) MMDI, (B.) MDEV, (C.) k-MDEV, (D.) AIDE and (E.) MARS. Liver stiffness before and after repositioning in the MRI scanner is defined as G*₁ and G*₂ respectively. Each volunteer has three datapoints corresponding to the three tested frequencies. The Bland-Altman analysis suggests that the MDEV method has the best performance in this context with the smallest interval of 95% limits of agreement.

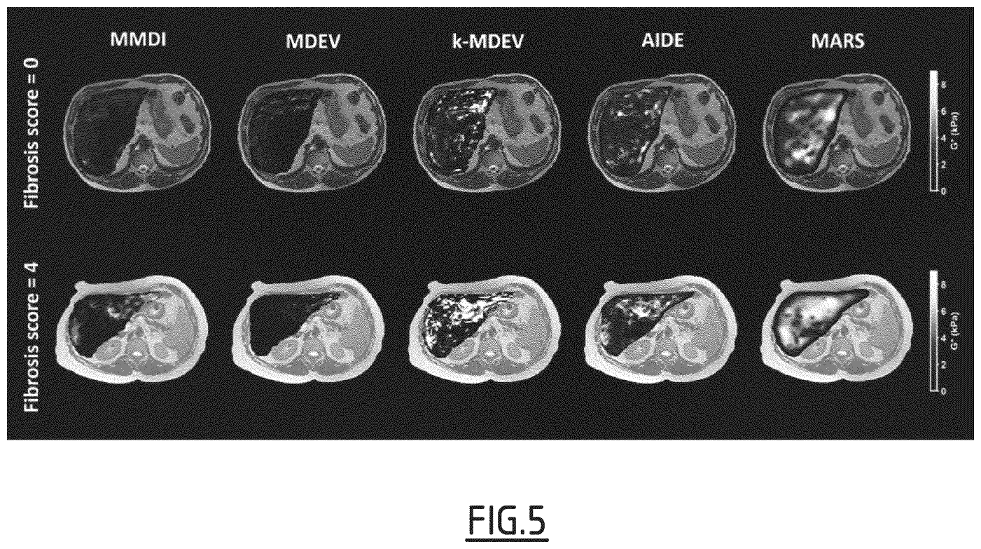

FIG. 5 illustrates the stiffness maps reconstructed by each method for a patient with fibrosis score of 0 (upper row) and for a patient with fibrosis score of 4. On the map provided by each method, high pixel intensities are located at the same locations in the liver. Qualitatively, the stiffness values appear higher in the F4 patient than in the F0 patient regardless of the applied method, and

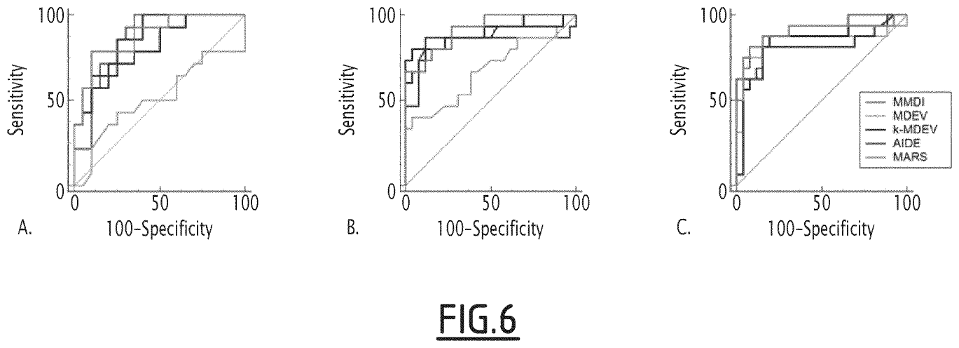

FIG. 6 shows the receiver operating curves of each method in diagnosing advanced fibrosis at (A.) 40 Hz, (B.) 60 Hz and (C.) 80 Hz. At 40 Hz, MARS shows the best diagnostic performance in detecting advanced fibrosis (AUC=0.88, p<0.0001), whereas at 60 Hz k-MDEV and MARS have the best diagnostic performance (AUC=0.91, p<0.0001 for both methods) and at 80 Hz, MMDI and MARS have the best AUC (AUC=0.90, p<0.0001 for both methods).

### Methods

### Subjects

Between November 2020 and February 2021, MRE data were acquired in a cohort of healthy volunteers to assess the repeatability of the liver mechanical parameters. In addition, to investigate the diagnostic potential, the reconstruction methods were used in 46 patients with biopsy-proven liver fibrosis. These patients were extracted from a larger cohort of patients (acquired between November 2018 and June 2021) recruited on the basis of established type 2 diabetes and steatosis. The study was performed in full compliance with ethical guidelines, with regulatory authorization from the local institutional review board and after having obtained informed consent from each volunteer and patient.

### MR Acquisitions

### MR Elastography Parameters

All experiments were conducted on a 3T MRI scanner (Ingenia, Philips Healthcare, Best, The Netherlands). A gradient echo MR elastography sequence was used (3 transverse slices with 10 mm thickness, 1.2 mm in-plane resolution, 400×450 mm² field of view, 20 ms echo time, 50 ms repetition time, 30° flip angle, 1 encoded direction along feet-head direction and 4 phase offsets). Synchronized mechanical vibrations of 40 Hz, 60 Hz and 80 Hz were successively used, they were generated with an acoustic driver placed on the upper abdomen. The acquisition included three 18 s breath holds. The acquisition sequence was used in rigorously identical fashion in phantoms, volunteers and patients.

### Phantom Study

MR elastography was performed in four homogeneous Zerdine (c) solid hydrogel phantoms (Model 0369, CIRS, Arlington, VA, USA). The four phantoms (C1, C2, C3, C4) provided respective Young's moduli of 3.5, 11.4, 28.6, 44.8 kPa according to the calibration data sheet provided by the manufacturer, corresponding to stiffness values of 1.7, 3.8, 9.5 and 14.9 kPa, respectively, considering a density of 1000 kg·m⁻³ and an idealized Poisson's ratio of 0.5. This range corresponds approximately to the stiffness of the liver with fibrosis ranging from absent to cirrhosis.

### Volunteer Study

To evaluate repeatability of the reconstruction methods, MR elastography acquisitions were used in a cohort of 20 volunteers with no diagnosed liver disease. The repeatability was assessed in a test-retest setting with volunteer repositioning (30 minutes interval between acquisitions). The volunteer study was carried out with informed consent under the appropriate regulatory authorizations (repeatability arm of the QuidNASH clinical trial NCT 03634098, research ethics committee 18.021-2018-A00311-54).

### Patient Study

The ability to diagnose advanced liver fibrosis (fibrosis≥F3 as determined at histopathology) with each reconstruction method was assessed in patients with type 2 diabetes and liver steatosis. The hepatic fibrosis stage was evaluated by an expert pathologist on histological sections of liver tissue biopsies according to the Kleiner system. Liver fibrosis was classified into five stages (0-4). Patients were dichotomized in a group with no or mild fibrosis (patients with fibrosis stages F0, F1 or F2) and a group with advanced fibrosis (patients with fibrosis stages F3 or F4). Patients were a randomized subset of the QuidNASH clinical trial (NCT 03634098, duly approved by the research ethics committee 18.021-2018-A00311-54), having undergone MR acquisitions during the July 2020-March 2021 period.

### Post-Processing

Liver stiffness was obtained using five different direct inversion methods. The first method was MMDI. MMDI is available as a commercial tool on the acquisition console on “Resoundant®” MRE-equipped MRI systems.

Two other methods were used: MDEV and KMDEV. These methods were tested using the implementation freely available on the Charite website corresponding to the following address: biogic-apps.charite.de.

Finally, two homemade methods (an implementation of the classical direct inversion and the MARS methods described above) are presented below. Both methods were developed using MATLAB (version 2020a, Mathworks, Natick, MA, USA).

The performance of five different methods were compared in phantoms, in healthy volunteers and in patients with nonalcoholic fatty liver disease and varying grades of fibrosis.

MMDI reconstruction was performed directly after MRE acquisition and stiffness maps were saved in DICOM format. For the MDEV and k-MDEV methods, fully anonymous raw MRE data matrices in matlab format were uploaded into the bioqic server (bioqic-apps.charite.de), which provided stiffness and shear wave speed (c) maps from MDEV and k-MDEV methods, respectively. To compare the methods with the same parameter, shear wave speed maps were converted into stiffness maps according to:

$$G *= ρ {c}^{2}$$

### Region of Interest Positioning and Data Extraction

The same region of interest (ROI) was placed on the stiffness maps provided by each method. As the acquisition method used is coupled to MMDI, the ROIs were placed on the stiffness maps reconstructed with this method. They were positioned for each slice according to the confidence threshold mask provided by the manufacturer. A threshold mask covering the whole liver (without areas to place ROIs) were considered as necessitating exclusion of the dataset from further analysis. Then, the same ROls were placed on the stiffness maps obtained with the other methods. To account for the disparity in ROI size for each slice, the average stiffness was determined as,

$$G *= \frac{{\sum }_{k} \overline{{G}_{k}^{*}} \cdot {N}_{k}}{{\sum }_{k} {N}_{k}}$$

where k=1,2 and 3 is the slice number, G̅*̅ₖ̅ is the average stiffness on the ROI placed in slice n and Nₖ is the pixels number contained in the ROI placed on slice k.

### Statistical Analysis

For phantom investigations, linear regressions were used to estimate the agreement between the stiffness values obtained with each tested reconstruction method and the calibrated phantom stiffnesses. The slope and the fit root mean square deviation were evaluated. Statistical significance was considered for p values<0.05.

To evaluate the repeatability of each method, the Bland-Altman method was used, wherein the difference between the two repeated acquisitions (relative to their mean) was measured and plotted as a function of the mean values. The repeatability index was calculated as:

$$1.96 \cdot \sqrt{2 \times percentage standard {deviation}^{2}}$$

Statistical differences between fibrosis stages were analyzed with a nonparametric Kruskal-Wallis test. The performance for stiffness, reconstructed from each method, to diagnose advanced fibrosis (F3 or F4) was assessed by calculating the area under the operating curves (AUCs). Statistical analysis was performed using Medcalc version 20.014 software (Medcalc, Ostend, Belgium).

### Results

### Phantoms

Stiffness maps reconstructed with the different methods for the four phantoms were obtained. As expected, stiffness values differ between the four stiffness phantoms. However, the values were also different depending on the applied method. Specifically for phantom C4, the stiffness map for MDEV shows low intensity compared to the other maps.

The differences in stiffness values between the different methods across the four stiffness phantoms are detailed in FIG. 3 and table 1, where linear regression plots and their derived parameters are shown. The correlation between measured stiffness and calibrated phantom stiffness values was significant for each method at the three frequencies used, except for the MDEV method at 40 Hz and 60 Hz (p=0.214 and p=0.131, respectively). At 40 Hz, the slope between stiffness from the manufacturer and the stiffness from the reconstruction methods was closest to one with MARS (slope=0.62). The goodness of fit was high for AIDE and MARS (r²=0.99, p<0.0001 and r²=0.99, p=0.0008, respectively). At 60 Hz, k-MDEV showed a slope closest to one (slope=0.9), while MMDI and MARS had the best goodness of fit (r²=0.99, p=0.0002 and r²=0.99, p=0.008, respectively). Using a frequency of 80 Hz, k-MDEV still provided a slope closest to one (slope=0.8) and MDEV had the highest goodness of fit (r²=0.99, p=0.004). The slope obtained with the MARS method was systematically higher compared to the slope obtained with AIDE (40 Hz: slope_{AIDE}=0.49 vs slope_{MARS}=0.62; 60 Hz: slope_{AIDE}=0.59 vs slope_{MARS}=0.61; slope_{AIDE}=0.66 vs slope_{MARS}=0.67).

TABLE 1
Parameters of the linear regression between phantom stiffness provided
by the manufacturer and phantom stiffness provided with each method

| | Frequency | | | | | | | | |
|---|---|---|---|---|---|---|---|---|---|
| | 40 Hz | | | 60 Hz | | | 80 Hz | | |
| Parameters | Slope | r² | p | Slope | r² | p | Slope | r² | p |
| MMDI | 0.21 | 0.91 | 0.048 | 0.46 | 0.99 | 0.0002 | 0.64 | 0.98 | 0.012 |
| MDEV | 0.03 | 0.62 | 0.214 | 0.18 | 0.76 | 0.131 | 0.56 | 0.99 | 0.004 |
| k-MDEV | 0.11 | 0.93 | 0.031 | 0.90 | 0.98 | 0.01 | 0.80 | 0.96 | 0.021 |
| AIDE | 0.49 | 0.99 | <0.0001 | 0.59 | 0.98 | 0.008 | 0.66 | 0.97 | 0.02 |
| MARS | 0.62 | 0.99 | 0.0008 | 0.61 | 0.99 | 0.008 | 0.67 | 0.98 | 0.01 |

### Investigation of the Repeatability in Volunteers

FIG. 4 shows the Bland-Altman graphs of the patient repositioning repeatability for each method. Combining all frequencies in the repeatability analysis, the limits of agreement of the Bland-Altman plots were lower in the MDEV method [−20.0%; 24.0%] with a bias of 2.0%, while k-MDEV showed the largest interval for limits of agreement [−40.5%; 34.8%] with a bias of −2.8%. The other methods showed limits of agreement in the same range (MMDI: [−26.8%; 27.0%], bias=0.1%; AIDE: [−25.5%; 26.3%], bias=0.4%; and MARS: [26.2%, 28.8%], bias=1.3%).

MDEV showed the best repeatability index (31%), while k-MDEV had the highest repeatability index (53%). With the other methods, repeatability indexes of 37%, 38% and 39% were obtained for AIDE, MMDI and MARS, respectively.

### Diagnostic Performance to Determine Advanced Fibrosis in Patients

The cohort included 46 patients (83% men) with median age of 62 years (range 32-83 years). Based on the histopathological analysis, 27 patients (59%) were classified in the low or absent fibrosis group (F0, F1 or F2) and 19 patients (41%) were classified in the advanced fibrosis group (F3 or F4). Further clinical data are provided in Table 2. Imaging and biopsy were performed on the same day except for three patients in whom biopsy was performed 5, 21 and 33 days after imaging. Among the 46 patients included, 12 patients, 5 patients and 4 patients were excluded from the analysis at 40 Hz, 60 Hz and 80 Hz, respectively because of the region of interest exclusion criterion defined above.

TABLE 2
Patient characteristics

| Parameter | Value |
|---|---|
| Number of patients | 46 |
| Men / Women | 38 / 8 |
| Age (mean ± standard deviation) | 61 ± 10 |
| Mean body mass index ± standard | 32 ± 5 |
| deviation (kg/m²) | |
| Fibrosis stage | |
| 0 | 14 |
| 1 | 8 |
| 2 | 5 |
| 3 | 14 |
| 4 | 5 |

FIG. 5 shows stiffness maps reconstructed at 60 Hz with each method for patient with fibrosis score F0 and patient with fibrosis score F4. As expected, liver stiffness increases with fibrosis score. Nevertheless, visually this increase is less obvious with MDEV than with the other methods.

TABLE 1
Stiffness values obtained with the different
methods at each fibrosis score and frequency

| | | Fibrosis stage | | | | |
|---|---|---|---|---|---|---|
| f_{exc} | Method | 0 | 1 | 2 | 3 | 4 |
| 40 | MMDI | 1.7 | 2.1 | 2.4 | 2.5 | 2.7 |
| | | [0.8; 2.4] | [1.8; 2.8] | [1.9; 2.8] | [1.9; 3.0] | [2.2; 3.8] |
| | | n = 11 | n = 7 | n = 2 | n = 10 | n = 5 |
| | MDEV | 0.9 | 1.0 | 1.0 | 1.0 | 0.7 |
| | | [0.2; 1.2] | [0.7; 1.2] | [0.8; 1.2] | [0.7; 1.4] | [0.6; 1.0] |
| | | n = 11 | n = 7 | n = 2 | n = 10 | n = 5 |
| | k-MDEV | 1.1 | 2.1 | 2.8 | 2.2 | 5.3 |
| | | [0.4; 2.2] | [0.9; 3.4] | [2.2; 3.4] | [1.5; 4.7] | [3.1; 6.7] |
| | | n = 11 | n = 7 | n = 2 | n = 10 | n = 5 |
| | AIDE | 2.2 | 2.7 | 3.1 | 2.9 | 4.5 |
| | | [1.0; 3.0] | [2.3; 3.3] | [2.3; 4.0] | [2.5; 4.2] | [3.5; 5.0] |
| | | n = 11 | n = 7 | n = 2 | n = 10 | n = 5 |
| | MARS | 2.2 | 3.0 | 3.4 | 3.7 | 5.6 |
| | | [0.9; 3.5] | [2.6; 3.8] | [2.2; 4.6] | [2.4; 5.0] | [4.0; 6.5] |
| | | n = 11 | n = 7 | n = 2 | n = 10 | n = 5 |
| 60 | MMDI | 2.6 | 3.4 | 3.4 | 4.1 | 5.4 |
| | | [2.0; 3.4] | [2.7; 4.4] | [2.8; 4.3] | [1.8; 5.3] | [4.1; 5.9] |
| | | n = 13 | n = 8 | n = 5 | n = 10 | n = 5 |
| | MDEV | 1.6 | 2.0 | 1.5 | 1.9 | 2.2 |
| | | [1.2; 2.1] | [1.7; 2.0] | [0.2; 2.2] | [1.3; 2.6] | [1.5; 2.7] |
| | | n = 13 | n = 8 | n = 5 | n = 10 | n = 5 |
| | k-MDEV | 2.7 | 3.6 | 3.6 | 4.8 | 7.0 |
| | | [2.1; 3.8] | [2.9; 4.1] | [0.5; 4.7] | [2.9; 7.2] | [5.0; 13.3] |
| | | n = 13 | n = 8 | n = 5 | n = 10 | n = 5 |
| | AIDE | 2.9 | 3.5 | 3.6 | 4.3 | 5.7 |
| | | [2.3; 3.7] | [2.8; 4.2] | [3.3; 4.6] | [2.5; 5.8] | [5.0; 6.2] |
| | | n = 13 | n = 8 | n = 5 | n = 10 | n = 5 |
| | MARS | 3.6 | 4.0 | 4.1 | 5.2 | 6.9 |
| | | [2.2; 4.7] | [3.1; 5.2] | [3.4; 5.2] | [3.8; 6.7] | [6.3; 8.1] |
| | | n = 13 | n = 8 | n = 5 | n = 10 | n = 5 |
| 80 | MMDI | 3.8 | 4.5 | 4.4 | 5.9 | 8.5 |
| | | [2.9; 6.1] | [3.8; 5.2] | [3.6 5.4] | [3.9; 7.5] | [7.4; 9.9] |
| | | n = 13 | n = 8 | n = 5 | n = 11 | n = 5 |
| | MDEV | 2.4 | 2.8 | 2.6 | 3.4 | 4.0 |
| | | [2.0; 2.9] | [2.0; 4.0] | [2.4; 3.3] | [1.8; 4.9] | [3.3; 4.9] |
| | | n = 13 | n = 8 | n = 5 | n = 11 | n = 5 |
| | k-MDEV | 4.5 | 1.4 | 5.1 | 6.5 | 9.4 |
| | | [3.4; 12.7] | [4.0; 7.5] | [3.7; 6.6] | [3.5; 19.2] | [8.3; 11.7] |
| | | n = 13 | n = 8 | n = 5 | n = 11 | n = 5 |
| | AIDE | 4.0 | 4.2 | 4.5 | 5.0 | 7.2 |
| | | [2.8; 5.2] | [3.6; 5.8] | [3.8; 5.3] | [3.0; 7.7] | [7.1; 7.8] |
| | | n = 13 | n = 8 | n = 5 | n = 11 | n = 5 |
| | MARS | 5.3 | 5.2 | 5.5 | 6.7 | 8.1 |
| | | [3.2; 6.5] | [4.2; 7.2] | [4.8; 6.2] | [4.1; 9.5] | [7.9; 8.7] |
| | | n = 13 | n = 8 | n = 5 | n = 11 | n = 5 |

Note:
Median data;
Data in brackets are minimum and maximum stiffness values, and
f_{exc}: frequency of excitation.

The stiffness values obtained with the different methods are presented in table 3. Qualitatively, with the exception of the MDEV method, the stiffness increased with the fibrosis score with all methods. The MARS method provided the highest stiffness values for each fibrosis stage, except for fibrosis score of 4 at 60 Hz and 80 Hz, where k-MDEV estimations were higher. The k-MDEV method also showed the largest range of values at each fibrosis stage.

Table 4 shows the results obtained from the Kruskal-Wallis analysis of the stiffness differences between fibrosis stages. MDEV at 40 Hz was the only method in which the stiffness did not vary significantly between fibrosis stages. MARS showed the best Kruskal-Wallis p values at 40 Hz and 60 Hz, whereas at 80 Hz MMDI had the best p value.

TABLE 4
P values obtained by Kruskal-Wallis to differential
stiffness values between fibrosis stages

| Method | 40 Hz | 60 Hz | 80 Hz |
|---|---|---|---|
| MMDI | 0.00323 | 0.00029 | 0.00016 |
| MDEV | 0.21180 | 0.03897 | 0.00161 |
| k-MDEV | 0.00077 | 0.00007 | 0.00278 |
| AIDE | 0.00033 | 0.00010 | 0.00136 |
| MARS | 0.00017 | 0.00005 | 0.00040 |

The diagnostic performance of stiffness determined with each tested method for its ability to diagnose advanced fibrosis (F3 or F4 vs. F0, F1 or F2), is presented in FIG. 6 and table 5. The MDEV method had the lowest AUC at 60 Hz compared to the other methods. The AUC of the stiffness in detecting advanced fibrosis was highest from maps reconstructed with the MARS method at 40 Hz (0.88, CI=[0.72, 0.97], p<0.0001). At 60 Hz, the AUC was highest using stiffness maps provided with k-MDEV and MARS (0.91, CI=[0.77, 0.97], p<0.0001 and 0.91, CI=[0.79, 0.98], p<0.0001, respectively). Finally, at 80 Hz the best diagnostic performance was obtained with stiffness values reconstructed from MMDI and MARS (0.90, CI=[0.76, 0.97], p<0.0001 and 0.90, CI=[0.77, 0.97], p<0.0001, respectively).

TABLE 5
Area under the operating curve (AUC) and associated significances
for the stiffness values estimated with the different reconstruction
methods for detecting advanced liver fibrosis

| | Frequency | | | | | |
|---|---|---|---|---|---|---|
| | 40 Hz | | 60 Hz | | 80 Hz | |
| Parameters | AUC | p | AUC | p | AUC | p |
| MMDI | 0.86 | <0.0001 | 0.84 | 0.0002 | 0.90 | <0.0001 |
| | [0.67, 0.94] | | [0.69, 0.93] | | [0.76, 0.97] | |
| MDEV | 0.53 | 0.7554 | 0.68 | 0.0588 | 0.85 | <0.0001 |
| | [0.36, 0.70] | | [0.51, 0.82] | | [0.70, 0.94] | |
| k-MDEV | 0.81 | 0.0001 | 0.91 | <0.0001 | 0.84 | <0.0001 |
| | [0.63, 0.91] | | [0.77, 0.97] | | [0.69, 0.93] | |
| AIDE | 0.87 | <0.0001 | 0.87 | <0.0001 | 0.82 | 0.0001 |
| | [0.71, 0.96] | | [0.73, 0.96] | | [0.67, 0.92] | |
| MARS | 0.88 | <0.0001 | 0.91 | <0.0001 | 0.90 | <0.0001 |
| | [0.72, 0.97] | | [0.79, 0.98] | | [0.77, 0.97] | |

Note:
Data in brackets are 95% confidence intervals

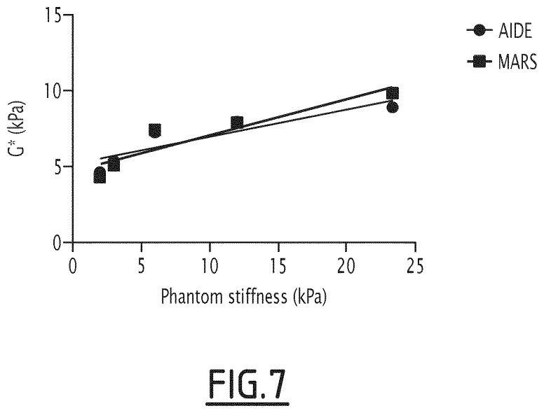

The Applicant has also carried out another experiment corresponding to the graph of FIG. 7.

For this, acquisition at 80 Hz were performed on a phantom which contains 4 inclusions with stiffnesses values of 2, 3, 12 and 23 kPa embedded in a medium with a stiffness value of 6 kPa.

MR elastography acquisitions were applied at 80 Hz as same parameters as those applied in homogeneous phantoms.

FIG. 7 shows the linear regression between stiffness provided by the manufacturer and the stiffness measured from AIDE and MARS algorithms.

The linear regression has a better correlation and a slope closest to 1 with MARS algorithm than AIDE algorithm (MARS: r²=0.86, p=0.02, slope=0.24; AIDE: r²=0.79, p=0.04, slope=0.18).

This shows that adapting the sampling ratio λ/α for each pixel enables to obtain a better reconstruction of the imaged tissue.

### DISCUSSION

In the current study, we presented a novel method based on the use of the spatial sampling ratio λ/α as quality criterion to reconstruct tissue mechanical parameters from multiresolution MRE displacement field images. The method was compared with four other MRE reconstruction methods for its ability to match calibrated stiffness values in phantoms, to produce stable results in a repeatability study and to help diagnosing advanced liver fibrosis in patients. The study was conducted in rigorously identical data sets, such that differences in performance were related to reconstruction effects rather than be caused by confounders from acquisition conditions.

All tested methods differed in their performance in phantoms, their repeatability, and their applicability for diagnosing liver fibrosis. MDEV tended to have worse performance than the other reconstruction methods, except for the repeatability in volunteers, where it displayed better results than the other methods. The k-MDEV method performed adequately in a clinical context, but its repeatability was not as good as that of the other methods, although it displayed satisfactory performance in the phantom study (excepted at low frequency). MMDI, AIDE and MARS methods had similar performance in volunteer repeatability and in the diagnosis of advanced fibrosis. AIDE and MARS showed better performance than MMDI for the quantification of phantom stiffness.

Compared to classic AIDE, MARS, which is an extension of AIDE, improved the agreement with calibrated phantom values and increased the diagnostic performance in detecting advanced fibrosis without negative impact on repeatability. The effect of the resampling was particularly noticeable at 40 Hz in phantoms. At low frequency, for a given stiffness the wavelength increased, resulting in the need for larger pixel size to maintain the spatial sampling ratio λ/α in an optimal regime. Moreover, resampling improved the diagnostic performance compared to classic AIDE, regardless of acquisition frequency, with AUC values with MARS that were systematically higher than with AIDE. The influence of MARS was less visible at 40 Hz, where the performance of AIDE was already high (AUC=0.88), but at 80 Hz where AIDE showed its lowest performance, MARS substantially improved the diagnostic performance.

The other methods had different performances with respect to frequency. MMDI and MDEV showed better performance at 60 and 80 Hz, while k-MDEV was optimal at 60 Hz to measure the phantom stiffness and to diagnose advanced liver fibrosis. Considering the results provided with all methods, the acquisition at 60 Hz showed the best results in phantoms and in patients to differentiate fibrosis stages and diagnose advanced fibrosis. A frequency of 60 Hz is generally used to assess liver fibrosis by MRE. This frequency provides a good compromise between high frequency which is attenuated by liver tissue and low frequency where wavelengths become too large relative to the acquisition resolution, especially in patients with high liver stiffness.

Performance of k-MDEV was markedly lower at low frequency in phantoms. In the volunteer study, large variability was also observed at 40 Hz relative to the other frequencies. Low frequencies are expected to be the most sensitive to spatial sampling artifacts in the noise-dominated regime. Interestingly, the MARS method, wherein the noise-dominated regime was compensated for by adjusting the spatial resolution to the local wavelength, seemed less prone to the large variability otherwise observed at 40 Hz, as evidenced by the better performance at 40 Hz in phantoms, and by the slightly reduced variance seen in the low frequency datapoints of the volunteer study. The improvement at 40 Hz was also evident in the patient study, where MARS detected fibrosis stages with higher statistical significance and had higher area under the ROC curve relative to k-MDEV, although the difference in AUC between the two methods was not significant. MARS provided similar performance at all frequencies, indicating a potential benefit of the resampling step in the MARS method. The adaptation to wavelength inherent of the MARS method is especially valuable because the mechanical wavelength of the tissue is not entirely under operator control and because the choice of acquisition resolution is constrained by other factors such as acquisition time, signal loss when decreasing voxel size, bandwidth, acceleration factor, and anatomical detail required for the disease of interest. These constraints are sometimes incompatible with spatial sampling ratio optimization, which may result in a variable sampling optimality within the region of interest and between patients. These factors are advantageously taken care of in the MARS method.

The MARS method almost systematically yielded higher stiffness values than the other methods. This could be interpreted as a beneficial effect of resampling, since the noise-dominated regime tended to decrease the apparent stiffness values. Higher values in MARS could be explained by readjustment of the spatial sampling ratio to lower values (through increase in voxel size), which would indeed result in higher apparent stiffness values.

In the k-MDEV results for fibrosis patients, the span of stiffness values tended to be larger in significant fibrosis (F>2), as observed by other groups. This is consistent with the behavior observed for k-MDEV at low frequency in phantoms, because both conditions have high spatial sampling ratios (because of high stiffness in patient with fibrosis and because of high wavelengths at low frequency in phantoms). Conversely in patients with low fibrosis stages (corresponding to shorter wavelengths), the MARS method showed a relatively larger range of values than k-MDEV.

In summary, four existing and one novel MRE reconstruction methods were compared in different situations and at different frequencies. The reconstruction method impacts the accuracy, reproducibility and diagnostic ability of MRE. The reconstructions provide different stiffness results according to the mechanical frequency of the acquisition and the patient stiffness. This underscores the need to consider the spatial sampling ratio as key component of the reconstruction quality. The claimed invention proposes to spatially modulate the spatial sampling with a novel MRE reconstruction approach.

1. Method for determining mechanical parameters of a tissue of a subject, the method being computer-implemented and comprising the following steps:
receiving at least one image of the tissue, each image being taken by a magnetic resonance elastography technique,
reconstructing stiffness maps with resampling of the shear wave displacement at several spatial resolutions,
estimating the shear wavelength at each pixel of each reconstructed stiffness map,
selecting for each pixel, the stiffness value of the reconstructed stiffness map fulfilling a selection criterion, the selection criterion being fulfilled when the ratio of the shear wavelength by the size of the pixel is comprised between 6 and 9, and
producing the final stiffness map by taking the selected stiffness value for each pixel.

2. Method for determining according to claim 1, wherein the selection criterion is fulfilled when the shear wavelength divided by the size of the pixel is the nearest to a value comprised between 6 and 8.

3. Method for determining according to claim 2, wherein the value is comprised between 6.5 and 7.5.

4. Method for determining according to, wherein during the reconstructing step, the number of spatial resolutions at which the shear wave displacement is resampled is superior to 3.

5. Method for determining according to claim 1, wherein each resampling of the shear wave displacement is performed with a multiplication factor, the multiplication factor being comprised between 0.5 and 1.5.

6. Method for determining according to claim 1, wherein the reconstructing step comprises an unwrapping operation of the phase signal of each image.

7. Method for determining according to claim 1, wherein the reconstructing step comprises a filtering operation with a Butterworth filter.

8. Method for determining according to claim 1, wherein the reconstructing step comprises finding the stiffness value by inversion of the Helmholtz wave equation.

9. Method for predicting that a subject is at risk of suffering from a chronic disease, the method for predicting at least comprising the step of:
carrying out the steps of a method for determining the mechanical parameters of the subject, to obtain determined parameters, the method for determining being according to claim 1, and
predicting that the subject is at risk of suffering from a chronic disease based on the determined parameters.

10. Method for diagnosing a chronic disease, the method for diagnosing at least comprising the step of:
carrying out the steps of a method for determining mechanical parameters of the subject, to obtain determined parameters, the method for determining being according to claim 1, and
diagnosing a chronic disease based on the determined parameters.

11. Method for identifying a therapeutic target for preventing and/or treating a chronic disease, the method comprising the steps of:
carrying out the steps of a method for determining mechanical parameters of a first subject, to obtain first determined parameters, the first subject being a subject suffering from the chronic disease, the method for determining being according to claim 1,
carrying out the steps of a method for determining mechanical parameters of a second subject, to obtain second determined parameters, the second subject being a subject not suffering from the chronic disease, method for determining being according to claim 1, and
selecting a therapeutic target based on the comparison of the first and second determined parameters.

12. Method for identifying a biomarker, the biomarker being a diagnostic biomarker of a chronic disease, a susceptibility biomarker of a chronic disease, a prognostic biomarker of a chronic disease or a predictive biomarker in response to the treatment of a chronic disease, the method comprising the steps of:
carrying out the steps of a method for determining mechanical parameters of a first subject, to obtain first determined parameters, the first subject being a subject suffering from the chronic disease, the method for determining being according to claim 1,
carrying out the steps of a method for determining mechanical parameters of a second subject, to obtain second determined parameters, the second subject being a subject not suffering from the chronic disease, the method for determining being according to claim 1, and
selecting a biomarker based on the comparison of the first and second determined parameters.

13. Method for screening a compound useful as a probiotic, a prebiotic or a medicine, the compound influencing a known therapeutic target, for preventing and/or treating a chronic disease, the method comprising the steps of:
carrying out the steps of a method for determining mechanical parameters of a first subject, to obtain first determined parameters, the first subject being a subject suffering from a chronic disease and having received the compound, the method for determining being according to claim 1,
carrying out the steps of a method for determining mechanical parameters of a second subject, to obtain second determined parameters, the second subject being a subject suffering from a chronic disease and not having received the compound, the method for determining being according to claim 1, and
selecting a compound based on the comparison of the first and second determined parameters.

14. Computer program product comprising instructions which, when the program is executed by a computer, cause the computer to carry out the steps of a method according to claim 1.

15. Computer-readable storage medium comprising instructions which, when executed by a computer, cause the computer to carry out the steps of a method according to claim 1.
